(19) United States
(12) Patent Application Publication
(10) Pub. No.: US 2025/0315451 A1
(43) Pub. Date: Oct. 9, 2025

(54) BATTERY DATA COMPRESSION METHOD, BATTERY DATA STORAGE METHOD AND RELATED DEVICES

(71) Applicant: SYL (NINGBO) BATTERY CO., LTD., Ningbo (CN)

(72) Inventor: Juntao CHU, Ningbo (CN)

(21) Appl. No.: 19/243,594

(22) Filed: Jun. 19, 2025

Related U.S. Application Data
(63) Continuation of application No. PCT/CN2023/139182, filed on Dec. 15, 2023.

(30) Foreign Application Priority Data
Dec. 19, 2022 (CN) 202211639103.3

(51) Int. Cl. G06F 16/28; G06F 16/25

(52) U.S. Cl. CPC G06F 16/285; G06F 16/258

(57) ABSTRACT

A battery data compression method, a battery data storage method, and related devices are provided. The battery data compression method includes: acquiring a to-be-compressed battery dataset, grouping battery data in the battery dataset according to a preset grouping algorithm to obtain one or more groups of battery data, and performing compression encoding on the one or more groups of battery data in a preset manner according to group categories, respectively. The battery data in each of the one or more groups originates from sequentially numbered adjacent batteries, and a difference between every individual piece of battery data in each of the one or more groups and reference data is within a first preset threshold range.

### CROSS-REFERENCE TO RELATED APPLICATIONS

This application is a continuation of international patent application No. PCT/CN2023/139182, filed on Dec. 15, 2023, which itself claims priority to Chinese patent application No. 202211639103.3, filed on Dec. 19, 2022, and titled “BATTERY DATA COMPRESSION METHOD, BATTERY DATA STORAGE METHOD AND BATTERY MANAGEMENT SYSTEM”. The contents of the above identified applications are hereby incorporated by reference herein in their entireties, except for any definitions, disclaimers, disavowals, and inconsistencies.

### TECHNICAL FIELD

The present disclosure relates to the field of battery data management technology, and in particular, to a battery data compression method, a battery data storage method, and related devices.

### BACKGROUND

With an escalating severity of environmental pollution and energy crisis, a development of green energy sources such as lithium batteries has accelerated significantly. Consequently, a demand for a large-scale energy storage system has grown substantially. The large-scale energy storage system usually includes a power battery pack including hundreds of single-cell batteries. To facilitate status monitoring and effective management of the power battery pack, battery data from hundreds of single-cell batteries must be collected and stored. However, the sheer volume of data presents several challenges: slow battery data transmission/processing, delayed storage operations, and excessive storage space consumption.

### SUMMARY

According to various embodiments of the present disclosure, a battery data compression method, a battery data storage method, and related devices are provided.

In a first aspect, a battery data compression method is provided, including: acquiring a to-be-compressed battery dataset, grouping battery data in the battery dataset according to a preset grouping algorithm to obtain one or more groups of battery data, and performing compression encoding on the one or more groups of battery data in a preset manner according to group categories, respectively. The battery data in each of the one or more groups of the of battery data originates from sequentially numbered adjacent batteries, and a difference between every individual piece of battery data in each of the one or more groups of battery data and reference data is within a first preset threshold range.

In a second aspect, a battery data storage method is provided, including: compressing to-be-stored battery data by the battery data compression method in the first aspect and storing the compressed battery data.

In a third aspect, a battery data compression apparatus is provided, including: means for acquiring a to-be-compressed battery dataset, means for grouping battery data in the battery dataset according to a preset grouping algorithm to obtain one or more groups of battery data, means for performing compression encoding on the one or more groups of battery data in a preset manner according to group categories, respectively. The battery data in each of the one or more groups of battery data originates from sequentially numbered adjacent batteries, and a difference between every individual piece of battery data in each of the one or more groups of battery data and reference data is within a first preset threshold range.

In a fourth aspect, a battery data storage apparatus is provided, including: means for compressing to-be-compressed battery data by the battery data compression method in the first aspect, and means for storing the compressed battery data.

In a fifth aspect, a controller is provided, including a processor and a memory. A computer program that is capable of being executed by the processor is stored in the memory, and the computer program is executed by the processor to implement the battery data compression method in the first aspect or the battery data storage method in the second aspect.

In a sixth aspect, a battery management system is provided, including at least one controller in the fifth aspect.

In a seventh aspect, a computer-readable storage medium is provided, on which a computer program is stored. The computer program is executed by a processor to implement the battery data compression method in the first aspect or the battery data storage method in the second aspect.

Beneficial effects of other technical solutions in the foregoing technical solutions are described in detail in a subsequent detailed description.

### BRIEF DESCRIPTION OF THE DRAWINGS

In order to provide a clearer explanation of the technical solution of the embodiments in the present disclosure, a brief introduction will be given to the accompanying drawings required for the embodiments. It should be understood that the following drawings only illustrate certain embodiments of the present disclosure and should not be considered as limiting the scope. For the skilled in the art, other relevant drawings can be obtained based on these drawings without creative labor.

FIG. 1 is a schematic block diagram of a controller in an embodiment of the present disclosure.

FIG. 2 is a flowchart of a battery data compression method in an embodiment of the present disclosure.

FIG. 3 is another flowchart of a battery data compression method in an embodiment of the present disclosure.

FIG. 4 is a schematic diagram of an encoding format when battery voltage data is not compressed.

FIG. 5 is a schematic diagram of an encoding format of a first preset format.

FIG. 6 is a schematic diagram of an encoding format of a second preset format.

FIG. 7 is a schematic diagram of an encoding format when battery temperature data is not compressed.

FIG. 8 is another schematic diagram of an encoding format of a first preset format.

FIG. 9 is another schematic diagram of an encoding format of a second preset format.

In the figures, 10 represents a controller, 100 represents a memory, 110 represents a processor, and 120 represents a communication module.

### DETAILED DESCRIPTION

To make objects, features, and advantages of the present disclosure more readily understood, the following describes specific embodiments of the present disclosure in detail with reference to the accompanying drawings. Although some embodiments of the present disclosure are shown in the accompanying drawings, it should be understood that the present disclosure may be implemented in various forms, and should not be construed as limiting the embodiments described herein. Instead, these embodiments are provided for a more comprehensive understanding of the present disclosure. It should be understood that the accompanying drawings and embodiments of the present disclosure are presented solely for exemplary purposes and are not intended to limit the protection scope of the present disclosure.

Firstly, a battery management system is provided in one or more embodiments of the present disclosure. Specifically, the battery management system includes multiple slave controllers, multiple master controllers and at least one main controller, multiple slave controllers are communicatively connected to a master controller, and multiple master controllers are communicatively connected to a master controller.

Alternatively, a slave controller is configured to collect battery data of a single-cell battery. The master controller may acquire battery data of multiple single-cell batteries by the multiple slave controllers. The main controller may acquire battery data of multiple single-cell batteries by the multiple master controllers.

It may be understood that both the multiple master controllers and the at least one main controller may perform corresponding data processing and data storage based on multiple battery data parameters.

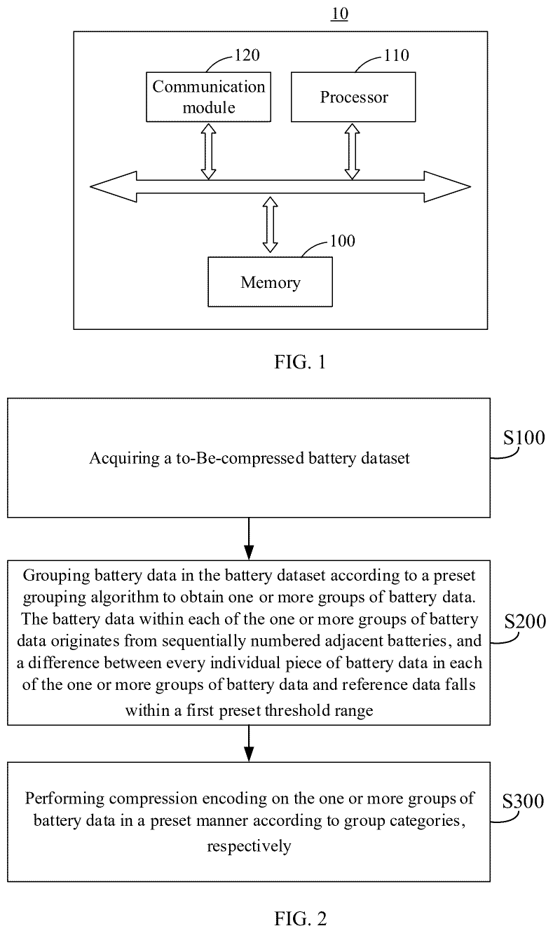

Furthermore, FIG. 1 is a schematic block diagram of a controller 10 in an embodiment of the present disclosure. Referring to FIG. 1, the controller 10 includes a memory 100, a processor 110, and a communication module 120. The memory 100, the processor 110, and the communication module 120 are electrically interconnected, either directly or indirectly, so as to facilitate data transmission or interaction. For example, such electrical connections may be implemented by one or more communication buses or signal lines.

The memory 100 is configured to store a computer program or data that can be executed by the processor 110. The memory 100 may include, but is not limited to, a Random Access Memory (RAM), a Read-Only Memory (ROM), a Programmable Read-Only Memory (PROM), an Erasable Programmable Read-Only Memory (EPROM), an Electric Erasable Programmable Read-Only Memory (EEPROM), or the like.

The processor 110 is configured to read/write data or a computer program stored in the memory 100, and execute a corresponding computer program to implement a battery data compression method or a battery data storage method provided in the embodiment of the present disclosure.

The communication module 120 is configured to establish a communicating connection between the controller 10 and other communication terminals by a network, enabling the transmission and reception of data over the network.

In at least one embodiment, the controller 10 may serve as the foregoing master controller, or the foregoing main controller. In other words, the battery management system includes at least one controller 10.

It should be understood that the structure shown in FIG. 1 is merely a schematic diagram of the controller 10, and the controller 10 may further include more or fewer components than those shown in FIG. 1, or have different configurations from those shown in FIG. 1. The components shown in FIG. 1 may be implemented by hardware, software, or a combination thereof.

Alternatively, a computer-readable storage medium is provided in the present disclosure, and a computer program is stored on the computer readable storage medium. When being executed by a processor, the computer program implements the battery data compression method or the battery data storage method provided in the embodiment of the present disclosure.

The controller 10 in FIG. 1 may be used as an execution body, and a battery data compression method provided in the embodiment of the present disclosure is exemplarily described with reference to a flowchart. Specifically, FIG. 2 is a flowchart of a battery data compression method in an embodiment of the present disclosure. Referring to FIG. 2, the battery data compression method includes step 100 to step 300.

Step 100 includes acquiring a to-be-compressed battery dataset.

Alternatively, the battery dataset may include battery data from multiple batteries, generally structured as sequential battery data ordered by battery identifiers. A sequence of the battery sequence data may correspond to a specific order of battery numbers. For example, a battery dataset corresponding to 400 batteries may be organized as: {battery 1 data, battery 2 data, battery 3 data, . . . , battery 400 data}. Furthermore, the battery data in the battery dataset may be one of voltage data, temperature data, state of charge (SOC) data, and state of health (SOH) data.

In at least one embodiment, a to-be-compressed battery dataset may include exclusively one type of battery data. The battery data type herein may refer to: battery voltage data, battery temperature data, battery State of Charge (SOC) data (configured to indicate a remaining capacity of the battery), or battery State of Health (SOH) data.

In an embodiment, a compression operation in the embodiment of the present disclosure may be performed before a storage operation. It may be understood that to-be-stored data targeted by the storage operation is the to-be-compressed battery dataset acquired in step 100.

In another embodiment, the compression operation in the embodiment of the present disclosure may occur before a transmission operation. It may be understood that the to-be-transmitted data targeted by the transmission operation is the to-be-compressed battery dataset acquired in step 100.

Step 200 includes grouping battery data in the battery dataset according to a preset grouping algorithm to obtain one or more groups of battery data. The battery data within each of the one or more groups of battery data originates from sequentially numbered adjacent batteries, and a difference between every individual piece of battery data in each of the one or more groups of battery data and reference data falls within a first preset threshold range.

Alternatively, the sequentially numbered adjacent batteries may refer to consecutive battery numbering sequence. For example, a group of battery data may be structured as: {battery 1 data, battery 2 data, battery 3 data, . . . , battery 20 data}, and the group of battery data may be the data from batteries with consecutive numerical identifiers.

Alternatively, each of the one or more groups of battery data may have its own reference data. The reference data may be a user-defined value, or may be an average value of all battery data in a group.

Alternatively, the first preset threshold range may be a user-defined range.

Furthermore, the first preset threshold range may be a subset of a signed integer range that can be expressed by a minimum storage unit of the difference.

Alternatively, the minimum storage unit of the difference may be user-configured according to a characteristic of the battery data.

In an embodiment, the minimum storage unit of the difference may be configured as 0.5 byte (4-bit nibble). The signed integer range that can be expressed by 0.5 byte may be [−7, +7]. It may be understood that in this case, the first preset threshold range is a subset of [−7, +7], for example, [−5, +5].

In another embodiment, the minimum storage unit of the difference may be configured as 1 byte (8-bit nibble). The signed integer range that can be expressed by 1 byte may be [−127, +127]. It may be understood that in this case, the first preset threshold range is a subset of [−127, +127], for example, [−125, +125].

In another embodiment, the minimum storage unit of the difference may be configured as 2 bytes (16-bit nibble). The signed integer range that can be expressed by 2 bytes may be [−32767, +32767]. It may be understood that in this case, the first preset threshold range is a subset of [−32767, +32767], for example, [−32765, +32765].

In at least one embodiment, minimum storage units corresponding to battery data in different types may be different. For example, the minimum storage unit of the difference corresponding to the battery voltage may be 1 byte or 2 bytes. The minimum storage unit of the difference corresponding to the battery temperature, SOC data or SOH data may be 0.5 byte. Correspondingly, the first preset threshold range corresponding to the battery voltage may be ±125 mV (±125×10⁻³ V) or ±32767 mV (±32767×10⁻³ V), the first preset threshold range corresponding to the battery temperature may be ±7° C., and the first preset threshold range corresponding to the SOC data or the SOH data may be ±7.

In the battery data compression method provided in the embodiment of the present disclosure, the first preset threshold range may be limited to the subset of the signed integer range that is expressed by the minimum storage unit of the difference, so that obtained differences can be stored in the minimum storage unit, thereby avoiding data loss when the battery data is compressed.

In at least one embodiment, by the preset grouping algorithm, the battery data in the battery dataset is divided into one or more groups of battery data that meet a preset grouping condition. Herein, preset grouping condition may be that the battery data in each of the one or more groups of battery data originates from sequentially numbered adjacent batteries, and the difference between every individual piece of battery data and reference data in each of the one or more groups of battery data falls within the first preset threshold range.

Step 300 includes performing compression encoding on the one or more groups of battery data in a preset manner according to group categories, respectively.

In at least one embodiment, when a group is obtained by grouping according to step 200, compression encoding may be performed on this group of data in a present manner. When multiple groups are obtained by grouping according to step 200, compression encoding may be performed on the multiple groups of battery data in a present manner, respectively.

In an embodiment, compression encoding may be performed on the one or more groups of battery data in a first present manner, respectively.

Alternatively, the first preset format may include the following data items: the reference data of a current group and the difference between every individual piece of battery data and the reference data in the current group. The reference data may be placed before all differences, or may be placed after all the differences, which is not limited in the embodiment of the present disclosure.

It may be understood that in any group of battery data, values of the battery data may be proximal to each other, and the difference between the battery data and the reference data is within the first preset threshold range. Compared with an actual value of the battery data, a byte count occupied by the difference between the battery data and the reference data is less, and an actual value of each piece of original battery data may be converted into a difference between the actual value of the battery data and the reference data, so that a byte count corresponding to every individual piece of battery data may be reduced, thereby implementing compression of battery data.

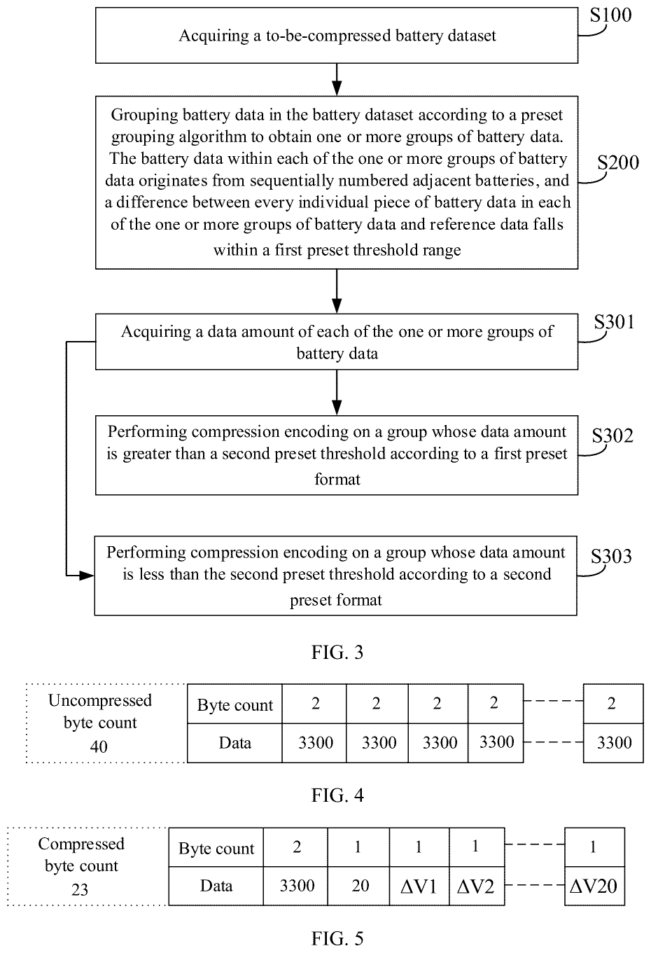

For example, referring to a group of data in FIG. 3 and FIG. 4, an average value of a group of battery voltages may be 3300 mV. For an actual value of battery data such as 3300 mV, the battery data may need to occupy two bytes, and after being converted into a difference (3300−3300=0) between the battery data and the average value, the battery data may be stored by only 1 byte (even 0.5 byte), thereby significantly reducing occupied storage space.

Alternatively, the reference data may be an average value of all battery data in a group.

In an embodiment, when the battery data in the battery dataset is grouped to obtain a group at step 200, an average value of the group of battery data and differences between each piece of the battery data and the average value may be stored. According to a type of the battery data, differences between every individual piece of battery data and the average value may be stored by 2 bytes, 1 byte, or 0.5 byte.

In the battery data compression method provided in the embodiment of the present disclosure, reference data may be set as the average value of all battery data in a group, so as to ensure that differences between every individual piece of battery data and the average value is relatively small, and the byte count occupied by the difference is less than the byte count occupied by the actual value of every individual piece of battery data, thereby reducing a total data amount of the battery data, reducing storage space occupied by the battery data, and effectively compressing the battery data.

Alternatively, the reference data may be an average value of all battery data in a group, and the first format may further include a data amount of the battery data in the current group.

Alternatively, the data amount of the battery data in the current group is configured to identify and parse compressed data. A sequence of the reference data, the quantity, and the difference may be set according to an actual requirement.

In an embodiment, the first preset format may be: the reference data+the quantity+a difference between the battery 1 data and the reference data, a difference between the second battery data and the reference data, . . . , and a difference between the n-th battery data and the reference data.

Specifically, referring to FIG. 5 or FIG. 8, FIG. 5 provides an example of battery voltage encoding for a single-cell battery. Reference data (3300) may be stored by 2 bytes, the quantity (20) of data of the current group may be stored by 1 byte, and a difference (ΔV1, ΔV2, . . . , or ΔV20) between every individual piece of battery data and the reference data may be stored by 1 byte. FIG. 8 provides an example of battery temperature encoding for a single-cell battery. Reference data (6) may be stored by 1 byte, the quantity (400) of data of the current group may be stored by 1 byte, and a difference (Δt1, Δt2, . . . , or Δt400) between each battery temperature and the reference data may be stored by 0.5 byte.

Alternatively, when a cluster of batteries is mounted, most cells belong to the same process and batch. Therefore, most battery states are proximal to each other, and values of battery data are proximal to each other, and only a few batteries have individual differences. Based on this feature of battery data, a compression method in the embodiment of the present disclosure is provided. On one hand, battery data whose values are proximal to each other may be divided into a group, so that battery data in the group may be relatively consistent and the difference may be relatively small, thereby facilitating subsequent compression encoding, and obtaining a better compression effect. On the other hand, in the same group, not only the values of the battery data may need to be proximal to each other, but also the battery data may need to be consecutive battery data. A correspondence between every individual piece of battery data and the number of the batteries may not need to be encoded in compression encoding of the consecutive battery data, thereby further ensuring a relatively small data amount after compression encoding. Therefore, effective compression of battery data may be implemented, the data amount of battery data may be reduced, transmission and storage efficiency of battery data may be improved, operation time may be shortened when an MCU stores battery data, and a storage operation or a transmission operation may be prevented from occupying MCU resources for too long, a time sequence of an embedded software may be more accurate, software reliability and real-time performance may be improved, memory utilization of a storage chip may be improved, more data may be maintained or storage chip space may be reduced, and costs may be reduced.

Alternatively, referring to FIG. 3, step 300 may further include step 301 and step 302.

Step 301 may include acquiring a data amount of each of the one or more groups of battery data, i.e., the quantity of battery data of each of the one or more groups of battery data.

Step 302 may include performing compression encoding on a group whose data amount is greater than a second preset threshold according to a first preset format.

The second present threshold may be a user-defined value, and a specific value of the second preset threshold may not be limited. For example, the second preset threshold may be 3 or 4.

In addition, related descriptions of the first preset format are described in detail above, and are not described herein again.

In an embodiment, the reference data may include an average value of all battery data in a group, and the first preset format may further include a data item: a data amount of the current group. Other contents of the present embodiment are described in detail above, and details are not described herein again.

In at least one embodiment, although the data item of reference data is added, when a data amount of a to-be-compressed group is relatively large, a reduced byte count after compression may be far greater than an increased byte count of the reference data. It may be understood that when the data amount of the to-be-compressed group is relatively large, better compression effect may be obtained by compressing the group. Therefore, compression encoding may be performed on the group whose data amount is greater than the second preset threshold according to the first preset format.

Alternatively, referring to FIG. 3, after step 301, the method may further include step 303. Step 303 may include performing compression encoding on a group whose data amount is less than the second preset threshold according to a second preset format. The second preset format may include the following data item: an actual value of every individual piece of battery data.

Alternatively, the second preset format may further include a data item: a data amount of the current group.

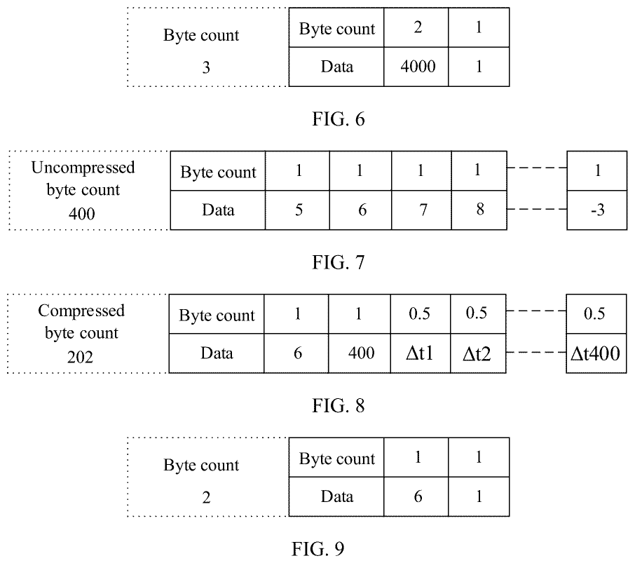

Alternatively, referring to FIG. 6, a schematic diagram of encoding a battery voltage data group whose data amount is less than the second preset threshold in the second preset format is provided, and the battery voltage data group may include an actual value (4000) of a single-cell battery voltage and a data amount (1). FIG. 9 shows a schematic diagram of encoding a battery temperature data group whose data amount is less than the second preset threshold in the second preset format, and the battery temperature data group may include an actual value (6) of a single-cell battery temperature and a data amount (1).

In at least one embodiment, when the data volume of a to-be-compressed group is relatively small, a difference between a reduced byte count and an increased byte count of the reference data may be relatively small. In this case, a compression operation may not need to be performed on the group, an actual value of battery data may be directly reserved, a compression operation with a relatively poor compression effect nay be avoided, and overall efficiency may be improved.

In an embodiment, the preset grouping algorithm at step 200 may include step 201 and step 202.

Step 201 may include determining whether deviant data exists in the battery dataset.

The deviant data may include battery data having a deviation from the reference data outside the first preset threshold range.

Step 202 may include: if yes, determine demarcation data based on the deviant data, dividing the battery dataset into two subsets based on the demarcation data, treating the two subsets as new battery datasets, respectively, and returning to the step 201.

In a specific embodiment, firstly, a difference between every individual piece of battery data and reference data in the battery dataset is calculated, and then a size relationship between each difference and the first preset threshold range is obtained one by one to determine whether there is a difference not in the first preset threshold range, so as to determine whether there is the deviant data.

In at least one embodiment, when only one piece of deviant data exists, the deviant data may be treated as the demarcation data. When two or more pieces of deviant data exist, one piece of deviant data may be selected as the demarcation data.

Furthermore, battery data that is far forward or far backward may be selected from all deviant data as the demarcation data. For example, in the battery dataset {battery 1 data, battery 2 data, battery 3 data, . . . , battery 400 data}, the deviant data may include 100th battery data, 210th battery data, 300th battery data, and 380th battery data. The 100th battery data (far forward) or the 380th battery data (far backward) may be selected as the demarcation data.

Furthermore, the demarcation data may be treated as an element of any subset.

In another specific embodiment, a sliding window may be used to slide through the battery dataset according to a preset sequence, and it may be accessed that whether current battery data in the sliding window is the deviant data. If the battery data in the current sliding window is not the deviant data, the sliding window may continue to slide to next battery data to access the deviant data, if all battery data in the battery dataset is accessed, it may be accessed that no deviant data exists in the battery dataset. If the battery data in the current sliding window is the deviant data, the sliding of the sliding window may be stopped, and the current battery data in the sliding window may be treated as the demarcation data.

For example, the battery dataset may be {battery 1 data, battery 2 data, battery 3 data, . . . , battery 400 data}, the preset sequence may be from the battery 1 data to the battery 400 data, it may be first accessed whether the battery 1 data is the deviant data, if no, the sliding window may be sliding to the battery 2 data, and it may be accessed whether the battery 2 data is deviant data, if no, the sliding window may be sliding to the battery 3 data by analogy, and when the sliding window is sliding to the battery 400 data, there is still no deviant data, it may be accessed that there is no deviant data in the battery dataset.

Alternatively, in a sliding process, for example, when the sliding window is sliding to the battery 200 data and it is accessed that the battery 200 data is deviant data, the sliding may be stopped, and the battery 200 data may be demarcation data. Furthermore, after the demarcation data is determined, the battery data may be divided into: a first subset including battery data preceding the demarcation data, and a second subset including the demarcation data and subsequent battery data.

In at least one embodiment, when there is no deviant data in the battery dataset, the battery dataset may be treated as a group.

Alternatively, deviant data in the battery dataset may be queried, the demarcation data may be determined based on the deviant data, and the battery dataset may be divided into two subsets based on the demarcation data, until there is no deviant data in the battery dataset, and relatively high grouping efficiency may be implemented.

In at least one embodiment, the battery data compression method may include step 1 to step 5.

Step 1 may include acquiring a to-be-compressed battery dataset and treating the to-be-compressed battery dataset as a battery dataset to be grouped. The battery data in the battery dataset may include one of voltage data, temperature data, SOC data, or SOH data.

Step 2 may include sliding a window through the battery dataset according to a preset sequence to access whether current battery data in the sliding window is deviant data. The deviant data may include battery data having a deviation from the reference data outside a first preset threshold range, and the reference data may include an average value of all battery data in the battery dataset.

Step 3 may include: if yes, stopping the sliding, treating the current battery data in the sliding window as demarcation data, dividing the battery data into: a first subset including battery data preceding the demarcation data, and a second subset including the demarcation data and subsequent battery data, treating the two subsets as new battery datasets, and returning to step 2.

Step 4 may include: if no, determining whether all battery data in the battery dataset is determined, if yes, determining that no deviant data exists in the battery dataset, and treating the battery dataset as a group; if no, continuing to slide the sliding window to next battery data to determine the deviant data.

Step 5 may include acquiring a data amount of each of the one or more groups of battery data according to the grouping results obtained at step 3 and step 4, performing compression encoding on a group whose data amount is greater than a second preset threshold according to a first preset format, performing compression encoding on a group whose data amount is less than the second preset threshold according to a second preset format. The first preset format may include the following data items: an average value of the current group, a data amount of the current group, and a difference between every individual piece of battery data and the average value. The second preset format may include the following data items: an actual value of every individual piece of battery data.

It should be noted that the “step 1” and “step 2” are merely used as an example of an introduction sequence. In some alternative embodiments, the steps may also occur in an order different from that indicated in the example. To facilitate understanding of the foregoing embodiments, an example may be provided.

There are 400 battery voltages in the battery dataset. Firstly, an average voltage of 400 batteries may be calculated, and then a difference between the voltage of each battery and the average voltage may be calculated from forward to backward (from battery 1 to battery 400).

In the present embodiment, when all the differences between voltages of 400 batteries and the average voltage are less than or equal to 125 mV, voltage data of the 400 batteries may be treated as a group.

In the present embodiment, it is assumed that the difference between the battery voltage of the battery 200 and the average value of the batteries is greater than 125 mV, voltage data of the battery 1 to the battery 199 may be treated as a subset A, and voltage data of the battery 200 to the battery 400 may be treated as a subset B. The average voltage value of the subset A and the average voltage value of the subset B may be obtained, respectively. The difference between the voltage of each battery and the new average voltage value from forward to backward, and it is determined whether there is a battery voltage having the difference greater than 125 mV by analogy, until all battery voltage data is divided.

To illustrate beneficial effects of the foregoing embodiments, the following embodiment is provided.

In at least one embodiment, an actual voltage value of a single-cell battery may be stored by 16 bits of 2 bytes, and a difference between the actual voltage value of the single-cell battery and the average value (the reference data) may be stored by 8 bits of 1 byte.

In the present embodiment, FIG. 4 is a schematic diagram of an encoding format when battery voltage data is not compressed. FIG. 5 is a schematic diagram of an encoding format of a first preset format. FIG. 6 is a schematic diagram of an encoding format of a second preset format.

With 400 batteries in an energy storage system as an example, 800 (400*2) bytes may be required for the uncompressed battery voltage data.

In the present embodiment, it is assumed that 400 battery voltages are in relatively high consistency. For example, all the differences between the 400 battery voltages and the average voltage value may be in a range of 125 mV. Referring to FIG. 5, the average voltage value may occupy 2 bytes, and the data amount of single-cell batteries may occupy 1 byte. The difference between the voltage of each single-cell battery and the average voltage value may occupy 1 byte. After 400 battery voltage data are compressed, a total of 403 bytes may be required, and the compression of the 400 battery voltage data may reduce space by about 50%.

In the present embodiment, when battery inconsistency is considered, and it is assumed that 5% of the batteries are inconsistent, 400*5%=20 batteries may be inconsistent.

In a possible embodiment, when the 20 batteries are 20 consecutive batteries and are ranked first or last, the byte count occupied by the battery voltage data may be 424 bytes including the average value (2 bytes), the quantity (1 byte), the differences (380 bytes), and inconsistent battery voltage (20*2+1 bytes), and the compression of the 400 battery voltage data may reduce space by about 47%.

In another possible embodiment, when the 20 batteries are 20 consecutive batteries and are arranged in the middle, the 400 batteries may be divided into 1-200 batteries, 201-220 batteries (inconsistent batteries), and 221-400 batteries. The byte count occupied by the 1-200 batteries may be 203 bytes including the average value (2 bytes), the quantity (1 byte), and the differences (200 bytes), the byte count occupied by 201-220 batteries (inconsistent batteries) may be 41 bytes, and the byte count occupied by 221-400 batteries may be 183 bytes including the average value (2 bytes), the quantity (1 byte), the differences (180 bytes), 400 battery voltage data may occupy 203+41+183=427 bytes, and the compression of the 400 battery voltage data may reduce space by about 47%.

In still another possible embodiment, when the 20 batteries are evenly distributed in 20 battery groups in the strictest operating condition, every 20 conventional batteries include one inconsistent battery, and a difference between a voltage of the inconsistent battery and an average voltage of the remaining 19 batteries is not within a range of ±125 mV, referring to FIG. 5 and FIG. 6, after the compression, the byte count may be 500 bytes (22 bytes*20 groups+3 bytes*20 batteries), which may reduce space by about 38%, and also reduce storage operation time by 35%.

In at least one embodiment, an actual temperature value of each single-cell battery may be stored by 8 bits of 1 byte, and a difference between the actual temperature value of the single-cell battery and an average value may be stored by 4 bits of 0.5 byte. The 8 bits of 1 byte (0xff) may be split into higher 4 bits and lower 4 bits, the higher 4 bits may indicate an average temperature difference of the (2n−1)th battery, the lower 4 bits may indicate an average temperature difference of the 2n-th battery, 0 may indicate a temperature difference of 0, 1 to 7 may indicate temperature differences of −1 to −7, and 8 to e may indicate temperature differences of +1 to +7.

In the present embodiment, FIG. 7 is a schematic diagram of an encoding format when battery temperature data is not compressed. FIG. 8 is another schematic diagram of an encoding format of a first preset format. FIG. 9 is another schematic diagram of an encoding format of a second preset format.

With 400 batteries in the energy storage system as an example, the 400 batteries may be connected in series in 20 battery groups. 400 (400*1) bytes may be required for the uncompressed battery temperature data (referring to FIG. 7).

In the present embodiment, when battery inconsistency is not considered, an average temperature and the battery temperature data amount after compression may occupy 1 byte, respectively, and each single-cell battery temperature difference may occupy 0.5 byte. Therefore, 202 bytes may be required for compressed battery temperature data (referring to FIG. 8), and the compression of the battery temperature data may reduce space by about 50%. When battery inconsistency is considered, and it is assumed that 5% of the batteries are inconsistent, 400*5%=20 batteries may be inconsistent. When the 20 batteries are 20 consecutive batteries and are ranked first or last, the byte count occupied by the 20 batteries may be 213 bytes including the average temperature (1 byte), the data amount (1 byte), the temperature differences (190 bytes), and temperatures of inconsistent batteries (20+1 bytes), and compression of the 400 battery temperature data may reduce space by about 47%.

In the present embodiment, when the 20 batteries are 20 consecutive batteries and are arranged in the middle, the 400 batteries may be divided into 1-200 batteries, 201-220 batteries (inconsistent batteries), and 221-400 batteries. The byte count occupied by the 1-200 batteries may be 102 bytes including the average temperature (1 byte), the data amount (1 byte), and the temperature differences (100 bytes), the byte count occupied by 201-220 batteries (inconsistent batteries) may be 21 bytes, and the byte count occupied by 221-400 batteries may be 92 bytes including the average temperature (1 byte), the data amount (1 byte), and the temperature differences (90 bytes). The 400 battery temperature data may occupy 102+21+92=215 bytes, and the compression of the 400 battery temperature data may reduce space by about 47%.

In the present embodiment, when the 20 batteries are evenly distributed in the 20 battery groups in the strictest operating condition, every 20 conventional batteries include one inconsistent battery. Referring to FIG. 9, each inconsistent battery temperature may occupy 2 bytes. After the compression, the byte count may be 280 bytes (12 bytes*20 groups+2 bytes*20 batteries), which may reduce space by about 30%.

It should be noted that, in the embodiments provided in FIG. 4 to FIG. 9, the first byte count may be set to facilitate display of technical effect, which does not indicate that this field exists in actual code.

In at least one embodiment, an actual SOC/SOH value of a single-cell battery may be stored by 8 bits of 1 byte.

With 400 batteries in the energy storage system as an example, the 400 batteries may be connected in series in 20 battery groups. 400 (400*1) bytes may be required for the uncompressed SOC/SOH data of the batteries.

In the present embodiment, when battery inconsistency is not considered, 202 bytes may be required for compressed SOC/SOH data of the batteries, and the compression of the SOC/SOH data of the batteries may reduce space by about 50%. When battery inconsistency is considered, and it is assumed that 5% of the batteries are inconsistent, 400*5%=20 batteries may be inconsistent. A case in which the 20 batteries are ranked first, last, or in the middle of the 400 batteries may be the same as a case of the battery temperature in the foregoing. Details are not described herein again.

In the present embodiment, when the 20 batteries are evenly distributed in the 20 battery groups in the strictest operating condition, every 20 conventional batteries include one inconsistent battery. 14 bytes may be required for a compressed battery group, 280 bytes may be required for compressed SOC/SOH data of the 400 batteries, which may reduce space by about 30%.

It may be understood that, in the foregoing provided strictest operating condition (5% of the batteries are inconsistent), the compressed space of the battery voltage, the battery temperature, the battery SOC data, and the battery SOH data may occupy 500+280+280+280=1340 bytes, the uncompressed space may occupy 800+400+400+400=2000 bytes, and the total space may be reduced by 33%, and operation time may be shortened by 33% (flash operation performed on 1024 bytes in one page in a sampling MCU may require 350 ms, which is shortened to 240 ms).

In the foregoing embodiment, the strictest operating condition is considered: 5% of the batteries are inconsistent. In a conventional operating condition of an actual application, a proportion of inconsistent batteries may be less than 5%, and a storage space saving effect may be better achieved by using the battery data compression method provided in the present disclosure. A specific embodiment may be as follows.

In at least one embodiment, the actual voltage value of a single-cell battery may be stored by 2 bytes, the difference between the actual voltage value of the single-cell battery and the average value may be stored by 1 byte, and 2% of the batteries are inconsistent.

In the present embodiment, 400 batteries in the energy storage system are used as an example. 800 bytes may be required for the uncompressed battery voltage data. It is considered that 2% of the batteries are inconsistent, i.e., 400*2%=8 batteries, and 8 batteries are evenly distributed in eight groups according to the strictest operating condition. 50 conventional batteries may include one inconsistent battery, and a difference between a voltage of the inconsistent battery and the average voltage may not be within a first preset threshold range (±125 mV). After the compression, the byte count may be (2+1+49*1+2)*8=432 bytes, which may reduce storage space by 46%.

In at least one embodiment, the actual SOC/SOH value of a single-cell battery may be stored by 1 byte, a difference between the actual SOC/SOH value and the average value may be stored by 0.5 byte, and 2% of the batteries are inconsistent.

In the present embodiment, 400 batteries in the energy storage system are used as an example. 400 bytes may be required for the uncompressed battery SOC/SOH data. It is considered that 2% of the batteries are inconsistent, i.e., 400*2%=8 batteries, and 8 batteries are evenly distributed in eight groups according to the strictest operating condition. 50 conventional batteries may include one inconsistent battery, and a difference between the SOC/SOH value of the inconsistent battery and an average SOC/SOH value of the remaining 49 batteries is not within a range of ±7. After the compression, the byte count may be 232 bytes (29 bytes*8). An original byte count may be 400 bytes, and space may be reduced by about 42%.

It may be understood that, in a case that 2% of the batteries are inconsistent, the unit battery voltage, the unit battery temperature, the compressed space of the battery voltage, the battery temperature, the battery SOC data, and the battery SOH data may occupy 432+232+232+232=1128 bytes, the uncompressed space may occupy 800+400+400+400=2000 bytes, and the total space may be reduced by 43%, and operation time may be shortened by 43%.

To further demonstrate the advantages of the embodiments of the present disclosure, an embodiment is provided. The actual voltage value of a single-cell battery may be stored by 4 bytes, the difference between the actual voltage value of the single-cell battery and the average value may be stored by 2 bytes.

In the present embodiment, 400 batteries in the energy storage system are used as an example. 1600 (=400*4) bytes may be required for the uncompressed battery voltage data. Since the difference between the actual voltage value of the single-cell battery and the average value is stored by 2 bytes, the battery voltage is usually in the range of 2000 mV to 4500 mV, and the voltage differences between all the single-cell battery voltages and the average voltage of 400 batteries are in the range of 32767 mV, the battery inconsistency may not be considered.

In the present embodiment, for the 400 batteries, the average voltage value may be identified by 2 bytes, and each voltage difference between the battery voltage and the average voltage may also occupy 2 bytes. The format may be used as follows: Start identifier (2 bytes)+average voltage (2 bytes)+differences between 400 battery voltages and the average voltage (2 bytes*400). Before compression: 1600 (=400*4) bytes, and after compression: 804 (=2+2+2*400) bytes, which reduces the space by about 50%.

It can be seen that when the single-cell battery voltage is stored by 4 bytes, the storage space occupation may be greatly reduced. A battery data storage method is provided in another embodiment of the present disclosure, including: compressing to-be-stored battery data by the battery data compression method, and then storing the compressed battery data. The battery data is compressed by the battery data compression method in the foregoing embodiments and stored, storage space required for data may be reduced, and storage costs may be reduced.

A battery data compression apparatus is provided in another embodiment of the present disclosure. Specifically, the battery data compression apparatus includes an acquiring module, a grouping module, and a first compression module.

The acquiring module is configured for acquiring a to-be-compressed battery dataset.

It may be understood that the acquiring module is configured to perform the foregoing step 100.

The grouping module is configured for grouping battery data in the battery dataset according to a preset grouping algorithm to obtain one or more groups of battery data. The battery data in each of the one or more groups of battery data originates from sequentially numbered adjacent batteries, and a difference between every individual piece of battery data in each of the one or more groups of battery data and reference data is within a first preset threshold range.

It may be understood that the grouping module is configured to perform the foregoing step 200.

The first compression module is configured for performing compression encoding on the one or more groups of battery data in a preset manner according to group categories, respectively.

It may be understood that the first compression module is configured to perform the foregoing step 300.

Alternatively, the first compression module is further configured for acquiring a data amount of each of the one or more groups of battery data, and performing compression encoding on a group whose data amount is greater than a second preset threshold according to a first preset format. It may be understood that the first compression module is configured to perform step 301 to step 302.

Alternatively, the grouping module is further configured for determining whether deviant data exists in the battery dataset, in which the deviant data includes battery data having a deviation from the reference data outside the first preset threshold range, if yes, determining demarcation data based on the deviant data, dividing the battery dataset into two subsets based on the demarcation data, treating the two subsets as new battery datasets, respectively, and returning to the step of determining whether deviant data exists in the battery dataset.

It may be understood that the grouping module is configured to perform step 201 to step 202.

Alternatively, the grouping module is further configured for sliding a window through the battery dataset to be grouped according to a preset sequence to access whether current battery data in the sliding window is the deviant data, if yes, stopping the sliding, treating the current battery data in the sliding window as the demarcation data, dividing the battery data into: a first subset including battery data preceding the demarcation data, and a second subset including the demarcation data and subsequent battery data.

Alternatively, the first compression module is further configured for performing compression encoding on a group whose data amount is less than the second preset threshold according to a second preset format. The second preset format includes the following data item: an actual value of every individual piece of battery data.

It may be understood that the first compression module is configured to perform the foregoing step 303.

A battery data storage apparatus is further provided in another embodiment of the present disclosure, including a second compression module and a storage module.

The second compression module is configured for compressing to-be-compressed battery data by the battery data compression method. The storage module is configured for storing the compressed battery data.

One skilled in the art may understand that all or a part of the processes in the methods in the foregoing embodiments may be implemented by a computer program instructing related hardware. The program may be stored in a computer-readable storage medium. When the program is executed, the processes in the foregoing method embodiments may be included. The storage medium may include a magnetic disk, an optical disc, a Read-Only Memory (ROM), a Random Access Memory (RAM), or the like. In the present disclosure, units described as separate parts may or may not be physically separate, and parts displayed as units may or may not be physical units, may be located in one place, or may be distributed on multiple network units. Some or all of the units may be selected according to actual requirements to implement the objectives of the solutions of the embodiments of the present disclosure. In addition, functional units in the embodiments of the present disclosure may be integrated into one processing unit, or each unit may exist alone physically, or two or more units may be integrated into one unit. The foregoing integrated unit may be implemented in a form of hardware, or may be implemented in a form of a software functional unit.

Although the present disclosure is disclosed above, the scope of protection of the present disclosure is not limited thereto. One skilled in the art may, without departing from the spirit and scope of the present disclosure, make various changes and modifications that fall within the protection scope of the present disclosure.

### INDUSTRIAL PRACTICALITY

The present disclosure provides a battery data compression method, a battery data storage method, and a related device, so as to effectively compress battery data, reduce the data amount of battery data, improve battery data transmission and storage efficiency, shorten operation time in which an MCU stores battery data, shorten time in which a storage operation or a transmission operation occupies an MCU resource, make a time sequence of an embedded software more accurate, improve software reliability and real-time performance, improve memory utilization of a storage chip, maintain more data or reduce storage chip space, and reduce costs.

Although the present disclosure has been disclosed in the form of preferred embodiments and variations thereon, it will be understood that numerous additional modifications and variations could be made thereto without departing from the scope of the present disclosure.

For the sake of clarity, it is to be understood that the use “of ‘a’ or ‘an’ throughout the present disclosure does not exclude a plurality, and ‘include’, ‘including’, ‘comprise’ or ‘comprising’ do not exclude other steps or elements.

What is claimed is:

1. A battery data compression method, comprising:
acquiring a to-be-compressed battery dataset;
grouping battery data in the battery dataset according to a preset grouping algorithm to obtain one or more groups of battery data, wherein the battery data in each of the one or more groups of battery data originates from sequentially numbered adjacent batteries, and a difference between every individual piece of battery data in each of the one or more groups of battery data and reference data is within a first preset threshold range; and
performing compression encoding on the one or more groups of battery data in a preset manner according to group categories, respectively.

2. The battery data compression method of claim 1, wherein performing compression encoding on the one or more groups of battery data in a preset manner according to group categories respectively further comprises:
acquiring a data amount of each of the one or more groups of battery data; and
performing compression encoding on a group whose data amount is greater than a second preset threshold according to a first preset format.

3. The battery data compression method of claim 2, wherein the first preset format comprises the following data items:
the reference data in a current group, and
the difference between every individual piece of battery data and the reference data in the current group.

4. The battery data compression method of claim 3, wherein the first preset format further comprises a data amount of the battery data in the current group.

5. The battery data compression method of claim 1, wherein the reference data comprises an average value of all battery data in a group.

6. The battery data compression method of claim 1, wherein the preset grouping algorithm comprises:
determining whether any deviant data exists in the battery dataset, wherein the deviant data comprises battery data having a deviation from the reference data outside the first preset threshold range,
if yes, determining demarcation data based on the deviant data, dividing the battery dataset into two subsets based on the demarcation data, treating the two subsets as new battery datasets, respectively, and returning to the step of determining whether any deviant data exists in the battery dataset.

7. The battery data compression method of claim 6, wherein determining whether any deviant data exists in the battery dataset, and if yes, determining demarcation data based on the deviant data, dividing the battery dataset into two subsets based on the demarcation data further comprises:
sliding a window through the battery dataset to be grouped according to a preset sequence to assess whether current battery data in the sliding window is the deviant data,
if yes, stopping the sliding, treating the current battery data in the sliding window as the demarcation data, dividing the battery data into:
a first subset comprising battery data preceding the demarcation data, and
a second subset comprising the demarcation data and subsequent battery data.

8. The battery data compression method of claim 2, wherein after acquiring the data amount of each of the one or more groups of battery data, the battery data compression method further comprises:
performing compression encoding on a group whose data amount is less than the second preset threshold according to a second preset format, wherein the second preset format comprises the following data item: an actual value of every individual piece of battery data.

9. The battery data compression method of claim 1, wherein the first preset threshold range is a subset of a signed integer range that is expressed by a minimum storage unit of the difference.

10. The battery data compression method of claim 1, wherein the battery data in the battery dataset is one of voltage data, temperature data, state of charge (SOC) data, or state of health (SOH) data.

11. A battery data storage method, comprising: compressing to-be-stored battery data by the battery data compression method of claim 1, and storing the compressed battery data.

12. A battery data compression apparatus, comprising:
means for acquiring a to-be-compressed battery dataset;
means for grouping battery data in the battery dataset according to a preset grouping algorithm to obtain one or more groups of battery data, wherein the battery data in each of the one or more groups of battery data originates from sequentially numbered adjacent batteries, and a difference between every individual piece of battery data in each of the one or more groups of battery data and reference data is within a first preset threshold range; and
means for performing compression encoding on the one or more groups of battery data in a preset manner according to group categories, respectively.

13. A battery data storage apparatus, comprising:
means for compressing to-be-compressed battery data by the battery data compression method of claim 1; and
means for storing the compressed battery data.

14. A controller, comprising a processor and a memory, wherein a computer program that is capable of being executed by the processor is stored in the memory, and the computer program is executed by the processor to implement the battery data compression method of claim 1.

15. The controller of claim 14, wherein performing compression encoding on the one or more groups of battery data in a preset manner according to group categories respectively further comprises:
acquiring a data amount of each group of the one or more groups of battery data; and
performing compression encoding on a group whose data amount is greater than a second preset threshold according to a first preset format.

16. A controller, comprising a processor and a memory, wherein a computer program that is capable of being executed by the processor is stored in the memory, and the computer program is executed by the processor to implement the battery data storage method of claim 11.

17. A battery management system, comprising at least one controller of claim 14.

18. A battery management system, comprising at least one controller of claim 16.

19. A computer-readable storage medium, on which a computer program is stored, wherein the computer program is executed by a processor to implement the battery data compression method of claim 1.

20. A computer-readable storage medium, on which a computer program is stored, wherein the computer program is executed by a processor to implement the battery data storage method of claim 11.
